(19) United States
(12) Patent Application Publication
(10) Pub. No.: US 2013/0240980 A1
(43) Pub. Date: Sep. 19, 2013

(54) Schottky diode integrated into LDMOS

(71) Applicants: Venkat Raghavan, Union City, CA (US); Andrew D. Strachan, Santa Clara, CA (US)

(72) Inventors: Venkat Raghavan, Union City, CA (US); Andrew D. Strachan, Santa Clara, CA (US)

(73) Assignee: Texas Instruments Incorporated, Dallas, TX (US)

(21) Appl. No.: 13/506,001

(22) Filed: Mar. 19, 2012

(51) Int. Cl. H01L 27/06; H01L 21/329

(52) U.S. Cl. 257/328; 438/570; 257/E27.016; 257/E21.359

(57) ABSTRACT

In an LDMOS device leakage and forward conduction parameters are adjusted by integrating an Schottky diode into the LDMOS by blocking the formation of one or more n+ source regions and providing a metalized region adjacent to an underlying n-epitaxial region.

### FIELD OF THE INVENTION

The invention relates to LDMOS (laterally diffused metal oxide semiconductor) devices. The invention is applicable to LDMOS which is used as a power switch (able to switch amperes of current). The requirements of a POWER MOSFET (like the LDMOS) are to minimize switching losses. In particular it relates to LDMOS devices implemented in a (Bipolar CMOS DMOS) BCD process.

### BACKGROUND OF THE INVENTION

LDMOS (laterally diffused metal oxide semiconductor) transistors are commonly used in RF/microwave power amplifiers, e.g., in base-stations where the requirement is for high output power with a corresponding drain to source breakdown voltage usually above 60 volts. These transistors are fabricated by growing an epitaxial silicon layer on a more highly doped silicon substrate.

A typical LDMOS is shown in FIG. 1, which shows a n-epitaxial layer 100 grown on a p-epitaxial layer 102, which, in turn is grown on a p-substrate 104. In this depiction, an n-buried layer 106 is formed in the n-epi 100 on top of the p-epi 102. The LDMOS includes an n+ drain 110 formed in an n-well 112 with an n-drift region 114 extending underneath the poly gate 120. As shown in FIG. 1, the n+ source region 122 is formed in a p-body 124. A p+ implant 126 provides a contact to the p-body. The gate 120 is formed on a gate oxide 130.

One of the drawbacks of an LDMOS device is the conduction loss in the inherent body diode of the device. Also, due to minority carrier accumulation the reverse recovery time is slow. Hence the LDMOS suffers from high dynamic losses due to the slow reverse recovery times.

One prior art solution is to include an external Schottky diode. However due to the high inductance of the package and printed circuit board the benefits are diminished. This is illustrated in the circuit diagram of FIG. 2, which shows a buck converter circuit comprising a high side LDMOS device 200 and a low side LDMOS 202, with external Schottky diode 210. The inductance of the package and the inductance of the PCB are depicted as parasitic stray inductances Lp 220. As shown in FIG. 2, the LDMOS devices 200, 202 both define an internal body diode 240, 242, respectively. The inductance of the external Schottky diode can be reduced by placing the Schottky diode in the same package as the MOSFET, however this requires two devices in the same package, which requires a large amount of space.

### SUMMARY OF THE INVENTION

According to the invention, there is provided an LDMOS device comprising a MOSFET and a Schottky diode integrated into the device adjacent the MOSFET. The MOSFET may include a lightly doped n-type region, typically in the form of an n-epitaxial region in which the n+ source is formed, and the Schottky diode may be formed by providing a metal or metalized region that forms a diode with the lightly doped n-type region. The metalized region may be a silicide region e.g., cobalt silicide. The silicide may be arranged to abut a lightly doped intermediate region that abuts the lightly doped n-type region. The MOSFET may be a butted source body device with a p-body and the n+ source formed in the same active region. The lightly doped n-type region may be an n-epitaxial region and the lightly doped intermediate region may be defined by the p-body, which may be contacted by means of at least one p+ body contact region. The source may be divided into multiple n+ source regions by intermediate p-body regions. In order to provide a junction between the silicide and the n-epitaxial region the n+ source regions may be blocked in the region defining the Shottky diodes. The MOSFET may include an n+ source and an n+ drain formed in the n-epitaxial region, the n-epitaxial region being formed on a p-type region, e.g. a p-substrate or p-epitaxial region grown on a substrate. The p+ body contact region, p−-body, and n+ source may be electrically tied together, e.g., by means of a common metal layer. The n+ source may include multiple n+ source regions separated by p-body regions to increase the safe operating area of the LDMOS. Each Schottky diode may be surrounded by a p+ ring for edge termination to reduce leakage. The p+ ring may be defined by the p+ contact region to the p-body.

Further, according to the invention, there is provided a method of reducing forward conduction loss in an LDMOS device, comprising integrating a Schottky diode with the LDMOS device. The LDMOS device may include a lightly doped n-type region and the Schottky diode may be formed by forming a metal or metalized region adjacent the lightly doped n-type region. The lightly doped n-type region may comprise an n-epitaxial region, which may be formed on a p-region e.g., a p-well region or p-body. The LDMOS device may include an n+ source and an n+ drain. The n+ source may include multiple n+ source regions, which may be separated by p-type regions, e.g., regions of a p-body. The metal or metalized region may comprise a silicided region, e.g., a cobalt silicide. In order to allow the silicided region to be formed adjacent the n-epitaxial region the formation of one or more of the n+ source regions may be blocked. The number of blocked n+ source regions can be increased to further reduce forward conduction loss. Typically the n+ source regions of an LDMOS are formed in a p-body, thus the silicide may be spaced from the n-epitaxial region by the p-body. The silicide region may be formed over the p-body.

Still further according to the invention, there is provided a method of reducing reverse recovery time in an LDMOS device, comprising integrating a Schottky diode with the LDMOS device. The LDMOS device may include a lightly doped n-type region and the Schottky diode may be formed by forming a metal or metalized region adjacent the lightly doped n-type region. The lightly doped n-type region may comprise an n-epitaxial region formed on a p-bulk. The LDMOS device may include an n+ source and an n+ drain. The n+ source may include multiple n+ source regions, which may be separated by regions of the p-body. The metal or metalized region may comprise a silicided region, e.g., a cobalt silicide. In order to allow the silicided region to be formed adjacent the n-epitaxial region the formation of one or more of the n+ source regions may be blocked. Typically the n+ source regions of an LDMOS are formed in a p-body, thus the silicide may be spaced from the n-epitaxial region by the p-body. The silicide region may be formed over the p-body.

### BRIEF DESCRIPTION OF THE DRAWINGS

FIG. 1 is a cross-section through a typical LDMOS device as known in the art,

FIG. 2 is a circuit diagram of a prior art buck converter with external Schottky diode;

FIG. 3 shows a Schottky diode junction electron distribution diagram,

FIG. 4 shows a Schottky diode junction corresponding to the electron distribution diagram of FIG. 2,

FIG. 5 shows the typical waveforms for a synchronous buck converter,

FIG. 6 is a circuit diagram of one implementation of the invention that includes a buck converter with integrated Schottky diode,

FIG. 7 shows a top view of a prior art LDMOS,

FIG. 8 shows a top view of one embodiment of an LDMOS with integrated Schottky diode of the invention, and

FIG. 9 shows a sectional side view of another embodiment of an LDMOS with integrated Schottky diode of the invention.

### DETAILED DESCRIPTION OF THE INVENTION

The present invention provides an LDMOS device with integrated Schottky diode.

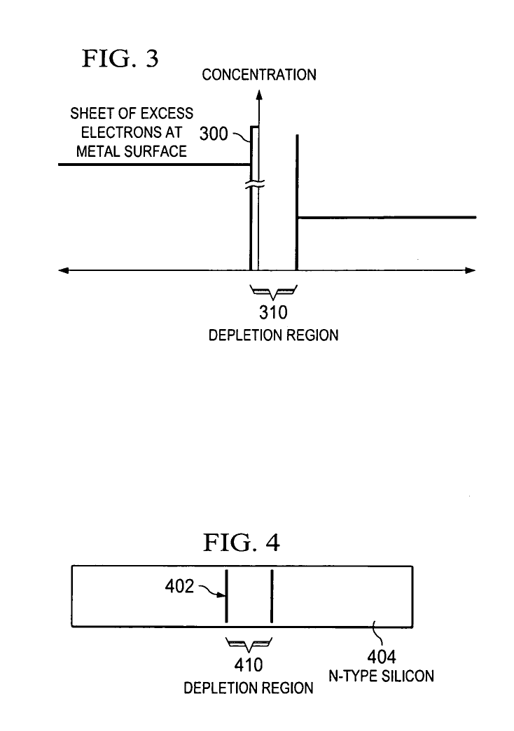

Schottky diodes are formed when a metal plate is brought into contact with lightly doped n-type silicon. As depicted in FIGS. 2 and 3, this creates a high concentration of electrons 300 at the surface 402 of the metal plate where it contacts the n-type silicon 404, and a depletion region 310, 410 between the metal plate and the n-type silicon, which shows the electron concentration across the Schottky diode. This provides the Schottky diode with a forward breakdown voltage Vf of about 0.3V compared to about 0.7V for a p-n diode formed between p-type silicon and n-type silicon. The benefits of a lower Vf are realized when the LDMOS is implemented in a circuit such as the buck converter of FIG. 2.

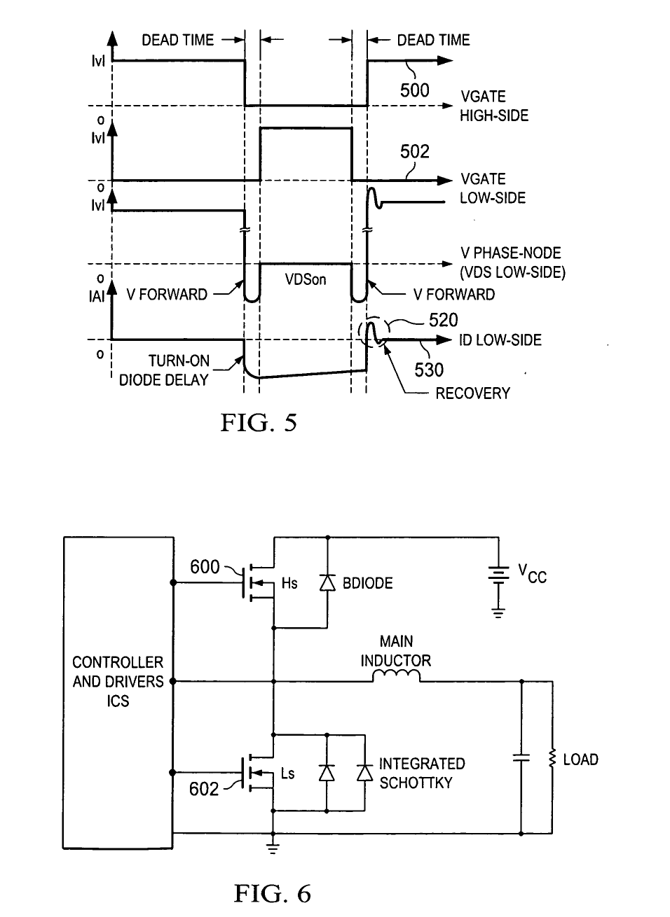

FIG. 5 shows the typical waveforms for a synchronous buck converter. As can be seen by comparing the voltage waveform on the gate of the high side LDMOS 100 (curve 500) with the voltage waveform on the gate of the low side LDMOS 102 (curve 502) there is a certain dead time (tdeadtime) 510 when the gate voltage on the LDMOS 100 changes but the gate voltage on LDMOS 102 has not yet changed. If Vf is the diode forward voltage, IL is the diode current, and f is the frequency, diode conduction loss is given by Vf×IL×tdeadtime×f. It will therefore be appreciated that the forward conduction loss is dependent on the forward breakdown voltage Vf. Therefore losses will be lower for a Schottky diode with a Vf of only 0.3V compared to the 0.7V for a p-n diode.

The Schottky diode also reduces the reverse recovery loss. Since the Schottky diode is a majority carrier device at low level injection, the minority carrier storage time is eliminated, thereby providing for a faster reverse recover time Trr. Trr is depicted by reference numeral 520 on curve 530.

Consider again the external Schottky diode circuit of FIG. 2. When the high side LDMOS turns on, the low side diode (body diode or external Schottky) has to recover the stored charge, also known as the diode reverse recovery charge Qrr. The diode recovery loss, which is a function of the input voltage Vin and the frequency, is given by Vin×Qrr×f. Since a Schottky diode has a lower Qrr than a regular p-n diode or an internal MOSFET body diode, it provides a lower diode recovery loss.

The present invention therefore provides substantial loss reduction, both regarding forward conduction losses as well as reverse recovery losses. One implementation of the LDMOS with integrated Schottky is shown in FIG. 6, which shows a buck converter circuit making use of LDMOS devices for the high side and low side devices 600, 602, respectively.

In order to integrate the Schottky diode without adding process steps and thus additional cost, the present invention implements the Schottky diode using the same process steps as those used for the LDMOS. In an LDMOS formed using a BCD process, the Schottky is also implemented in the BCD process flow.

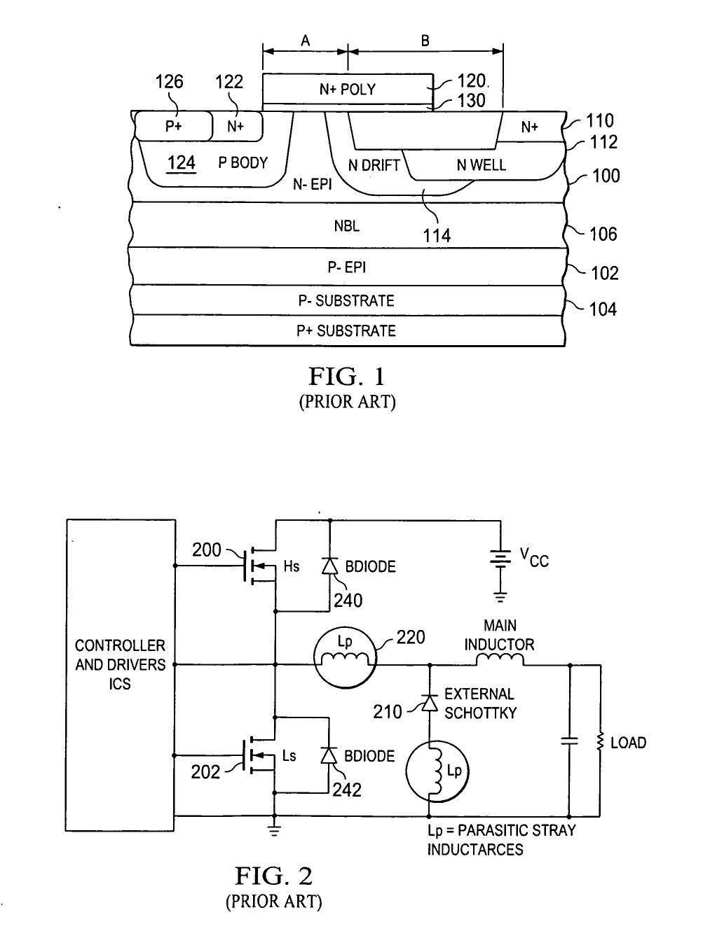

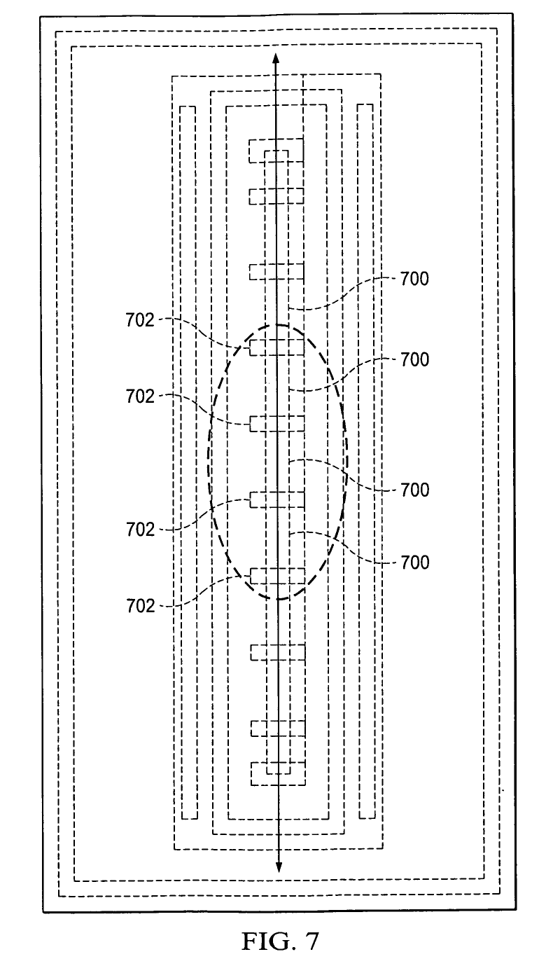

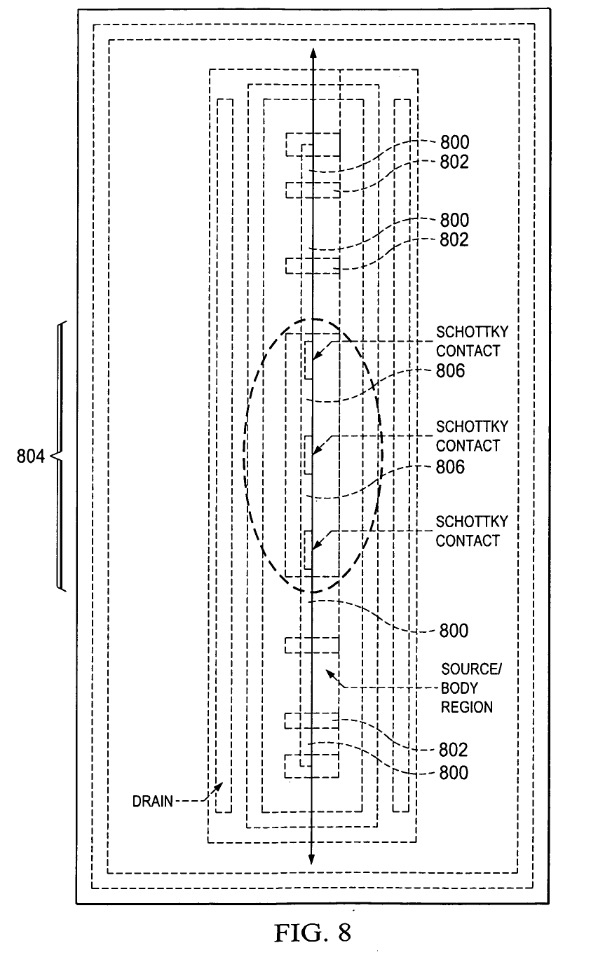

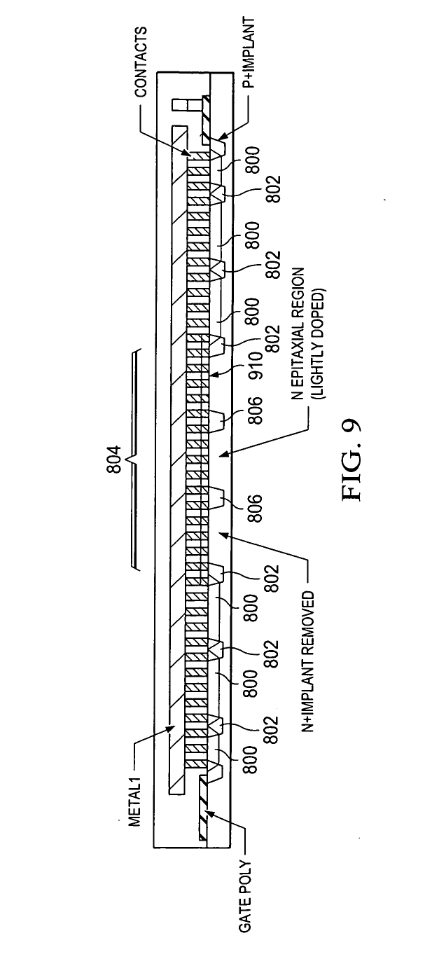

FIG. 7 shows a top view of the source side of a typical prior art LDMOS device. The source comprises multiple n+ source regions 700, each separated laterally from the next by a p+ body regions 702. The present invention integrates Schottky diodes into the LDMOS device by eliminating one or more n+ source regions from the LDMOS. This is shown in FIG. 8, which shows a top view of one embodiment of an LDMOS device of the invention. A section of the source has been eliminated by blocking the deposition of n+ impurities during the formation of the source, as depicted by the region 804, which was masked to avoid the formation of n+ source. In this embodiment, the region 804 covers an area that is separated into three regions by two p+ body contacts 806, as is shown more clearly in the sectional view of FIG. 9, thereby allowing three Schottky diodes to be formed. As can be seen in FIG. 8, the source regions 800 separated by the p+ body regions 802 are shown above and below the blocked region 804. A silicide layer 910 is formed to span the blocked region 804 to define and the anode of the three Schottky diodes. The cathode contact to the Schottky diodes is defined by the drain contact (not shown), which extends to the n-epi 912 via an n-well as best understood from the depiction of an LDMOS in FIG. 1. By determining how many of the n+ source regions are to be blocked it is possible to provide a trade-off between leakage and forward conduction. More or fewer such regions can be blocked to form a greater or smaller Schottky diode area.

By eliminating the highly doped n+ source from the region 804 a lightly doped region is provided in the form of an underlying epitaxial layer. This is best shown in FIG. 9, which shows a sectional side view of another embodiment of the source side of an LDMOS device of the invention. For ease of reference the embodiment of FIG. 9 uses the same reference numerals to depict similar structural elements as those in the FIG. 8 embodiment. The epitaxial layer 900 defines the cathodes of the integrated Schottky diodes of the invention. In order to provide an anode, a metalized region is formed over the epitaxial layer 900. In one embodiment of the invention a cobalt silicide layer 902 is formed over the epitaxial layer 900. Each Schottky diode includes at least one contact to define anode and cathode contacts. In the embodiment of FIG. 9 each Schottky diode is provided with three contacts 908 to the silicide layer 902. The contacts provide the anode contact to the Schottky diode. The electrical contact to the epitaxial region 900 in this embodiment is made by means of the drain contact, which contacts the n+ drain region formed in an n-well as best appreciated with respect to the prior art LDMOS device of FIG. 1 and also forms the cathode contact to the Schottky diodes. FIG. 1 shows the n+ drain 110 formed in the n-well 112.

The cobalt silicide forming the anode of the Schottky diodes will, if a typical LDMOS process is used, be formed on top of the p-body but will nevertheless provide a Schottky diode with the underlying lightly doped n-epitaxial region.

The present invention thus provides an elegant way of reducing forward conduction loss and reverse recovery time in an LDMOS while maintaining the same process steps. Therefore if a Bipolar CMOS DMOS (BCD) process is used in forming the LDMOS, the present invention allows the BCD process to be used in forming an integrated Schottky diode, in accordance with the invention.

In the above embodiments the Schottky diodes were formed in the source/body active region. Schottkys are leakier than regular diodes, hence, only a selected few n+ regions were removed in the source/body active region. The number of n+ source regions eliminated to support Schottky diodes depends on the degree to which high power current has to be supported by the device and the amount of leakage that is acceptable. It will also be noted that each Schottky diode region is surrounded by a p+ ring for edge termination, to reduce leakage. In the above embodiments this is achieved by shorting out the p+ body contact region 126, p-body 124 and n+ source regions 122 by means of a layer of cobalt salicide.

While the implementation was described with respect to particular embodiments, it will be appreciated that the integrated Schottky can be implemented in different ways to achieve integrated Schottky diodes in the source/body active region. Also as discussed above, the number of Schottky diodes created will vary depending on the application.

What is claimed is:

1. An LDMOS device comprising
a MOSFET and at least one Schottky diode integrated into the device adjacent the MOSFET.

2. An LDMOS device of claim 1, wherein the MOSFET includes a lightly doped n-type region.

3. An LDMOS device of claim 2, wherein the lightly doped n-type region comprises an n-epitaxial region in which the n+ source is formed.

4. An LDMOS device of claim 2, wherein the at least one Schottky diode is formed by providing a metal or metalized region that forms a diode with the lightly doped n-type region.

5. An LDMOS device of claim 4, wherein the metalized region comprises a silicide region.

6. An LDMOS device of claim 1, wherein the source is divided into multiple n+ source regions by intermediate p-body regions.

7. An LDMOS device of claim 6, wherein the n+ source regions have been blocked in the region defining the at least one Shottky diode.

8. An LDMOS device of claim 7, further comprising p+ body contact regions, at least some of the p+ body contact regions, p-body regions, and n+ source regions being electrically tied together to define a ring around the at least one Schottky diode.

9. A method of reducing forward conduction loss in an LDMOS device, comprising
integrating a Schottky diode into the LDMOS device by converting part of the LDMOS device into a Schottky diode.

10. A method of claim 9, wherein the LDMOS device includes a lightly doped n-type region and the Schottky diode is formed by forming a metal or metalized region adjacent the lightly doped n-type region.

11. A method of claim 10, wherein the LDMOS includes multiple n+ source regions, the method further comprising blocking the formation of one or more of the n+ source regions.

12. A method of claim 11, wherein the lightly doped n-type region comprises an n-epitaxial region and the multiple n+ source regions are separated by p-type regions.

13. A method of claim 11, wherein the metal or metalized region comprises a silicided region.

14. A method of reducing reverse recovery time in an LDMOS device, comprising integrating a Schottky diode into the LDMOS device by converting part of the LDMOS device into a Schottky diode.

15. A method of claim 14, wherein the LDMOS device includes a lightly doped n-type region and the Schottky diode is forming by forming a metal or metalized region adjacent the lightly doped n-type region.

16. A method of claim 15, wherein the lightly doped n-type region comprises an n-epitaxial region, and multiple n+ source regions are formed in the n-epitaxial region.

17. A method of claim 16, wherein in order to allow the silicided region to be formed adjacent the n-epitaxial region the formation of one or more of the n+ source regions is blocked.

18. A method of claim 17, wherein the Schottky diode is provided with anode and cathode contacts.

19. A method of claim 18, wherein the cathode contact is defined by one or more drain contacts to the LDMOS device.
